(19) United States
(12) Patent Application Publication
(10) Pub. No.: US 2014/0156924 A1
(43) Pub. Date: Jun. 5, 2014

(54) SEMICONDUCTOR MEMORY DEVICE WITH IMPROVED OPERATING SPEED AND DATA STORAGE DEVICE INCLUDING THE SAME

(71) Applicant: SK HYNIX INC., Icheon-si (KR)

(72) Inventors: Chun Woo JEON, Icheon-si (KR); Hwang HUH, Icheon-si (KR)

(73) Assignee: SK HYNIX INC., Icheon-si (KR)

(21) Appl. No.: 13/845,543

(22) Filed: Mar. 18, 2013

(30) Foreign Application Priority Data
Dec. 4, 2012 (KR) 10-2012-0139443

(51) Int. Cl. G11C 15/04

(52) U.S. Cl. CPC G11C 15/04
USPC 711/108

(57) ABSTRACT

A semiconductor memory device includes a power block configured to generate an internal voltage based on an external voltage which is applied through a power pad; a circuit block configured to operate according to the internal voltage and drive memory cells; and a CAM (content addressed memory) block configured to operate according to the external voltage and store setting information necessary for driving of the memory cells.

### CROSS-REFERENCES TO RELATED APPLICATION

The present application claims priority under 35 U.S.C. §119(a) to Korean application number 10-2012-0139443, filed on Dec. 4, 2012, in the Korean Intellectual Property Office, which is incorporated herein by reference in its entirety.

### BACKGROUND

1. Technical Field

The present invention generally relates to a semiconductor memory device, and more particularly, to a semiconductor memory device with improved operating speed and reduced standby current consumption, and a data storage device including the same.

2. Related Art

Semiconductor memory devices are generally divided into a volatile memory type and a nonvolatile memory type. While the volatile memory device loses stored data when the power supply is interrupted, the nonvolatile memory device can retain stored data even though the power supply is interrupted. Nonvolatile memory devices include various types of memory cells.

Depending upon the structure or the operating scheme of the memory cell, volatile memory devices may be divided into a static RAM (SRAM) using a flip-flop, a dynamic RAM (DRAM) using a capacitor, and a synchronous DRAM (SDRAM) operating in synchronization with an external device.

Depending upon the structure of the memory cell, nonvolatile memory devices may be divided into a flash memory device, a ferroelectric RAM (FeRAM) using a ferroelectric capacitor, a magnetic RAM (MRAM) using a tunneling magneto-resistive (TMR) layer, a phase change memory device (PCRAM) using a chalcogenide alloy, and a resistive memory device (ReRAM) using a transition metal oxide.

In a semiconductor memory device, an operating current refers to current which is consumed when the semiconductor memory device operates in an active mode such as in read, write (or program) and erase operations. Conversely, a standby current, also known as a leakage current, refers to current which is consumed when the semiconductor memory device operates in a standby mode. In general, peripheral circuits of the semiconductor memory device are deactivated in the standby mode. That is to say, while the semiconductor memory device operates in the standby mode, a power applied to the peripheral circuits is cut off to stop operations of the peripheral circuits of the semiconductor memory device.

If the power applied to the peripheral circuits is cut off while the semiconductor memory device operates in the standby mode, overall power consumption of the semiconductor memory device may improve. However, operating speed of the semiconductor memory device may decrease. In other words, if the semiconductor memory device switches from the standby mode to the active mode, the power should be resupplied to the peripheral circuits. Since peripheral circuits take time to stabilize due to the resupplied power, operating time or responding time of the semiconductor memory device may increase. Thus, there is a need for a semiconductor memory device with improved operating speed and a data storage device including the same.

### SUMMARY

In an embodiment of the present invention, a semiconductor memory device includes: a power block configured to generate an internal voltage based on an external voltage which is applied through a power pad; a circuit block configured to operate according to the internal voltage and drive memory cells; and a CAM (content addressed memory) block configured to operate according to the external voltage and store setting information necessary for driving of the memory cells.

In an embodiment of the present invention, the CAM block is activated regardless of an operation mode of the semiconductor memory device.

In an embodiment of the present invention, a data storage device includes: a semiconductor memory device; and a controller configured to control the semiconductor memory device, the semiconductor memory device including a power block configured to generate an internal voltage based on an external voltage which is applied through a power pad; a circuit block configured to operate according to the internal voltage and drive memory cells; and a CAM block configured to operate according to the external voltage and store setting information necessary for driving of the memory cells.

In an embodiment of the present invention, the semiconductor memory device is configured to operate in a power saving mode according to a power save command provided from the controller.

In an embodiment of the present invention, the CAM block is activated while the semiconductor memory device operates in the power saving mode.

In an embodiment of the present invention, a semiconductor system comprises a memory device configured to drive in response to a plurality of driving modes and a CAM block configured to continuously operate regardless of the plurality of driving modes.

### BRIEF DESCRIPTION OF THE DRAWINGS

Features, aspects, and embodiments are described in conjunction with the attached drawings, in which:

FIG. 1 is a block diagram showing a semiconductor memory device in accordance with an embodiment of the present invention;

FIG. 2 is a block diagram showing a power applying method of a power block and a CAM block in accordance with an embodiment of the present invention;

FIG. 3 is a timing diagram showing operations of the power block and the CAM block in accordance with an embodiment of the present invention;

FIG. 4 is a block diagram showing a data processing system including the semiconductor memory device in accordance with an embodiment of the present invention;

FIG. 5 is a diagram showing a memory card including the semiconductor memory device in accordance with an embodiment of the present invention;

FIG. 6 is a block diagram showing the internal configuration of the memory card shown in FIG. 5 and the connection relationship between the memory card and a host;

FIG. 7 is a block diagram showing an SSD including the semiconductor memory device in accordance with an embodiment of the present invention;

FIG. 8 is a block diagram showing the SSD controller shown in FIG. 7; and

FIG. 9 is a block diagram showing a computer system in which a data storage device including the semiconductor memory device in accordance with an embodiment of the present invention is mounted.

### DETAILED DESCRIPTION

In the present invention, advantages, features and methods will become more apparent after a reading of the following embodiments taken in conjunction with the drawings. The present invention may, however, be embodied in different forms and should not be construed as being limited to the embodiments set forth herein. Rather, these embodiments are provided to describe the present invention in detail to the extent that a person skilled in the art to which the invention pertains can easily enforce the technical concept of the present invention.

It is to be understood herein that embodiments of the present invention are not limited to the particulars shown in the drawings and that the drawings are not necessarily to scale and in some instances proportions may have been exaggerated in order to more clearly depict certain features of the invention. While particular terminology is used herein, it is to be appreciated that the terminology used herein is for the purpose of describing particular embodiments only and is not intended to limit the scope of the present invention.

As used herein, the term “and/or” includes any and all combinations of one or more of the associated listed items. It will be understood that when an element is referred to as being “on,” “connected to” or “coupled to” another element, it may be directly on, connected or coupled to the other element or intervening elements may be present. As used herein, a singular form is intended to include plural forms as well, unless the context clearly indicates otherwise. It will be further understood that the terms “includes” and/or “including” when used in this specification specify the presence of at least one stated feature, step, operation, and/or element, but do not preclude the presence or addition of one or more other features, steps, operations, and/or elements thereof.

Hereinafter, a semiconductor memory device and a data storage device including the same according to the present invention will be described below with reference to the accompanying drawings through various embodiments.

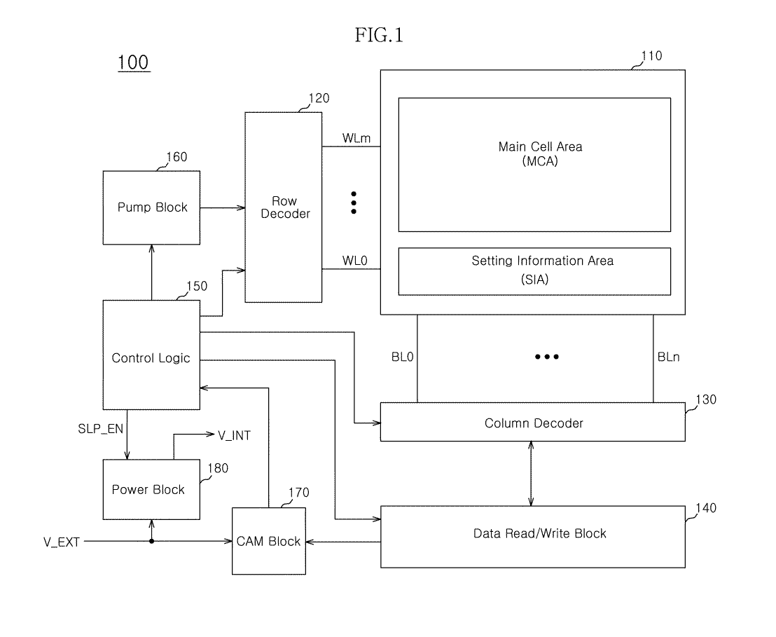

Referring to FIG. 1, a semiconductor memory device 100 may include a memory cell array 110, a row decoder 120, a column decoder 130, a data read/write block 140, a control logic 150, a pump block 160, a CAM (content addressed memory) block 170, and a power block 180.

The memory cell array 110 may include a main cell area (MCA) and a setting information area (SIA). The main cell area (MCA) may include memory cells for storing data provided from an external device (not shown). The setting information area (SIA) may include memory cells for storing setting information necessary for operations of the semiconductor memory device 100. The memory cells included in the main cell area (MCA) and the setting information area (SIA) may be arranged in regions where word lines WL0 to WLm and bit lines BL0 to BLn intersect.

Because the setting information area (SIA) is an area for storing setting information, the setting information area (SIA) may be an area hidden to a user. The setting information stored in the setting information area (SIA) may include at least one of a bias level and a bias applying time necessary for the operations of the semiconductor memory device 100, setting information of the control logic 150, failed address information, repair address information and redundancy information.

While power is applied to the semiconductor memory device 100 and an initializing operation is performed, the setting information stored in the setting information area (SIA) is read through the data read/write block 140. The read setting information is stored in the CAM block 170. For the sake of convenience in explanation, the CAM block 170 is shown as a separated function block. However, depending upon the contents of the setting information, the CAM block 170 may be included in each of the circuit blocks which drive the memory cell array 110 (for example, the row decoder 120, the column decoder 130, the data read/write block 140, the control logic 150 and the pump block 160). The setting information stored in the CAM block 170 may be referenced by the respective circuit blocks during the operations of the semiconductor memory device 100 (for example, the row decoder 120, the column decoder 130, the data read/write block 140, the control logic 150 and the pump block 160).

The row decoder 120 may be operated under the control of the control logic 150. The row decoder 120 may be connected with the memory cell array 110 through the word lines WL0 to WLm and configured to decode an address which is provided from the external device. The row decoder 120 may be configured to select and drive the word lines WL0 to WLm according to a decoding result. For instance, the row decoder 120 may provide a pumping voltage provided from the pump block 160, to the word lines WL0 to WLm as a word line voltage or a gate voltage.

The column decoder 130 may be operated under the control of the control logic 150. The column decoder 130 may be connected with the memory cell array 110 through the bit lines BL0 to BLn and configured to decode an address which is provided from the external device. The column decoder 130 may be configured to sequentially connect the bit lines BL0 to BLn with the data read/write block 140 by a predetermined unit according to a decoding result.

The data read/write block 140 may operate under the control of the control logic 150. The data read/write block 140 may be configured to operate as a write driver or a sense amplifier according to an operation mode. For example, the data read/write block 140 may be configured to store data provided from the external device to the memory cell array 110 in a program operation. In another example, the data read/write block 140 may be configured to read data from the memory cell array 110 in a read operation.

The control logic 150 may be configured to control operations such as read, write (or program) and erase operations of the semiconductor memory device 100 in response to control signals provided from the external device.

The pump block 160 may be configured to generate voltages necessary for operations which are being performed under the control of the control logic 150. While not shown, the pump block 160 may generate voltages on the basis of an external voltage V_EXT which may be provided from the external device or an internal voltage V_INT which may be provided from the power block 180.

The power block 180 may be configured to generate the internal voltage V_INT on the basis of the external voltage V_EXT which may be provided from the external device. While not shown, the power block 180 may include a power generation block to generate the internal voltage V_INT. The circuit blocks for driving the memory cell array 110, for example, the row decoder 120, the column decoder 130, the data read/write block 140, the control logic 150 and the pump block 160, may operate according to the internal voltage V_INT which may be generated from the power block 180.

The CAM block 170 of an embodiment of the present invention may directly receive the external voltage V_EXT. Thus, the CAM block 170 may always be activated according to a continuous providing of the external voltage V_EXT regardless of an operation mode. For example, the CAM block 170 may be activated when the semiconductor memory device 100 operates in an active mode such as in read, write (or program) and erase operations. Moreover, the CAM block 170 may be activated even when it operates in an inactive mode such as a power saving mode or a standby mode. As the CAM block 170 may always be activated according to the external voltage V_EXT, the setting information stored while the initializing operation is performed may be continuously retained. Thus, an operation for loading setting information from the setting information area (SIA) to the CAM block 170 may be omitted when the semiconductor memory device 100 switches from the inactive mode to the active mode. Therefore, a mode converting speed and an operating speed or a responding speed of the semiconductor memory device 100 may be improved. According to an embodiment of the present invention, the power block 180 may be configured to operate according to a sleep mode activation signal SLP_EN which may be provided from the control logic 150. A sleep mode is one of a plurality of inactive modes for reducing current consumption of the semiconductor memory device 100 as in the power saving mode or standby mode. Although the power saving mode, the standby mode and the sleep mode correspond to the inactive mode, the power saving mode or standby mode may be entered according to a chip select signal which may be applied to the semiconductor memory device 100. The sleep mode may be entered according to a specified command. The power block 180 may be configured to block input of the external voltage V_EXT when the semiconductor memory device 100 operates in the sleep mode. Further, the power block 180 may be configured to be provided a ground voltage while the semiconductor memory device 100 operates in the sleep mode. Thus, the power generation block (not shown) of the power block 180 can be discharged. Accordingly, standby current or leakage current consumed while the semiconductor memory device 100 operates in the sleep mode may be reduced.

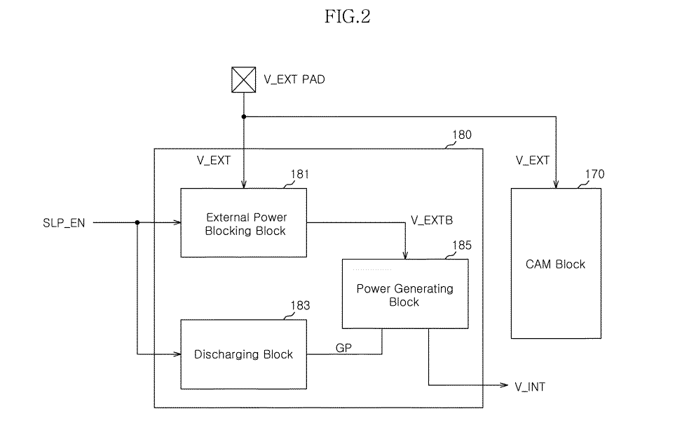

Referring to FIG. 2, the power block 180 may include an external power blocking block 181, a discharging block 183 and a power generating block 185. While not shown, the power generating block 185 may include a reference voltage generator for generating the internal voltage V_INT, a voltage converter, and so forth.

The external power blocking block 181 may be configured to operate according to the sleep mode activation signal SLP_EN. The external power blocking block 181 may be configured to receive the sleep mode activation signal SLP_EN in response to a sleep mode command SLP_CMD (not shown) which may be provided from the external device, when the semiconductor memory device 100 (see FIG. 1) enters the sleep mode. When the sleep mode activation signal SLP_EN is provided to the external power blocking block 181, the external power blocking block 181 may be operated to cut off a path between an external power pad V_EXT PAD and the power generating block 185. Thus, the power generating block may not receive the external voltage V_EXT.

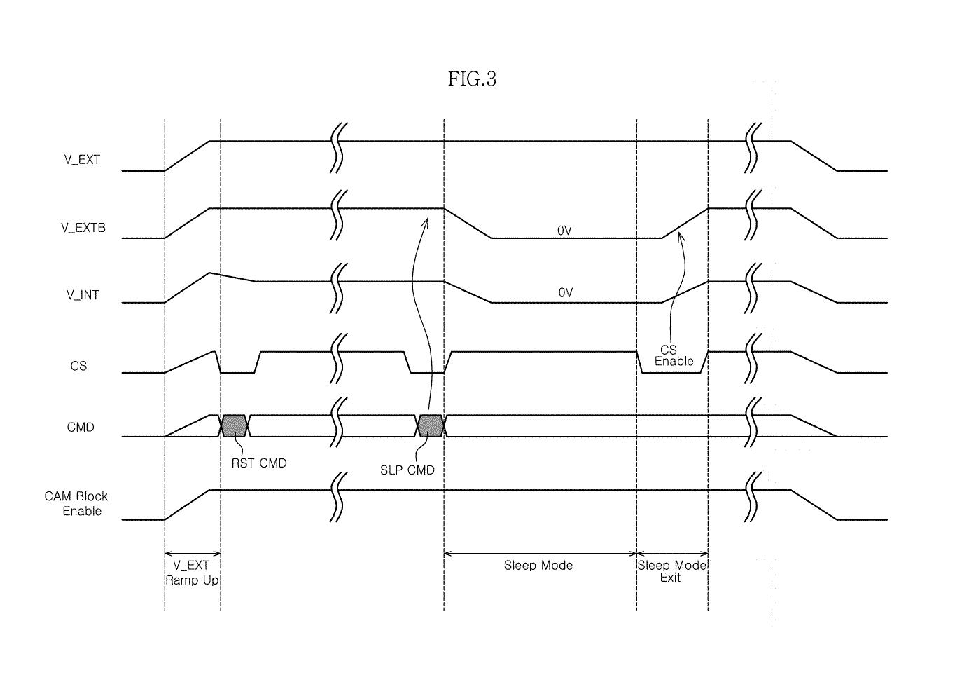

Namely, as shown in FIG. 3, if the semiconductor memory device 100 operates in the sleep mode, even though the enabled external voltage V_EXT is provided to the external power pad V_EXT PAD, the voltage V_EXTB, that is, an output level of the external power blocking block 181, is disabled because the external power blocking block 181 blocks the path between the external power pad V_EXT PAD and the power generating block 185. Accordingly, when the semiconductor memory device 100 operates in the sleep mode, even though the enabled external voltage V_EXT may be applied, the internal voltage V_INT may not be generated.

The discharging block 183 may be configured to operate according to the sleep mode activation signal SLP_EN. The discharging block 183 may be configured to discharge the power generating block 185 when the sleep mode activation signal SLP_EN is provided to the discharging block 183. For example, the discharging block 183 may be configured to provide a ground voltage to all input terminal nodes in the power generating block 185 through a ground path GP formed between the discharging block 183 and the power generating block 185 when the semiconductor memory device 100 operates in the sleep mode.

When the semiconductor memory device 100 enters the sleep mode, since the semiconductor memory device 100 does not perform any operation, a chip select signal CS may be deactivated. When the chip select signal CS is activated, the semiconductor memory device 100 may exit the sleep mode. Subsequently, when the semiconductor memory device 100 returns to a normal mode from the sleep mode, the external power blocking block 181 may provide the external voltage V_EXT to the power generating block 185. Also, when the semiconductor memory device 100 returns to the normal mode from the sleep mode, the ground voltage may no longer be provided to the discharging block 183. That is, the ground path GP between the discharging block 183 and the power generating block 185 break in accordance with the deactived sleep mode activation signal SLP_EN.

As mentioned above, the external voltage V_EXT provided through the external power pad V_EXT PAD may be directly applied to the CAM block 170, which may always be activated according to the external voltage V_EXT regardless of an operation mode. That is to say, as shown in FIG. 3, the CAM block 170 may always be activated when the semiconductor memory device 100 operates not only in an active mode but also in an inactive mode (for example, the sleep mode). Accordingly, the setting information stored in the CAM block 170 according to a reset command may always be retained.

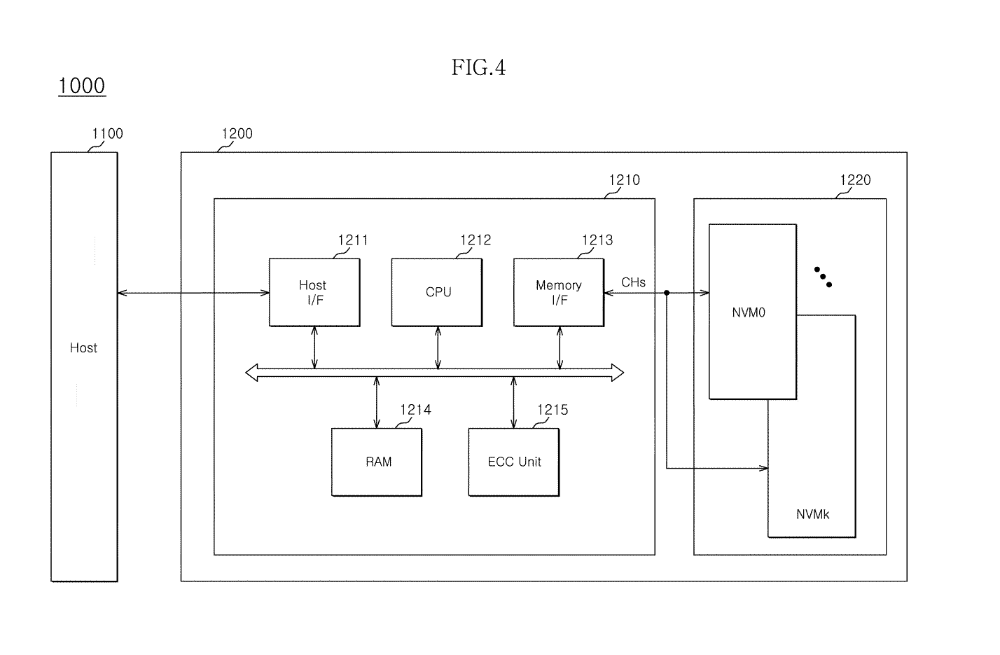

Referring to FIG. 4, a data processing system 1000 may include a host 1100 and a data storage device 1200. The data storage device 1200 may include a controller 1210 and a data storage medium 1220. The data storage device 1200 may be used by being connected to the host 1100 such as a desktop computer, a notebook computer, a digital camera, a mobile phone, an MP3 player, a game machine, and the like. The data storage device 1200 is also referred to as a memory system.

The controller 1210 may be connected to the host 1100 and the data storage medium 1220 and configured to access the data storage medium 1220 in response to a request from the host 1100. For example, the controller 1210 may be configured to control the read, program or erase operation of the data storage medium 1220. The controller 1210 may be configured to drive a firmware for controlling the data storage medium 1220.

The controller 1210 may include well-known components such as a host interface 1211, a central processing unit (CPU) 1212, a memory interface 1213, a RAM 1214, and an error correction code (ECC) unit 1215.

The central processing unit 1212 may be configured to control the general operations of the controller 1210 in response to a request from the host 1100. The RAM 1214 may be used as a working memory of the central processing unit 1212 and may temporarily store the data read from the data storage medium 1220 or the data provided from the host 1100.

The host interface 1211 may be configured to interface the host 1100 and the controller 1210. For example, the host interface 1211 may be configured to communicate with the host 1100 through one of various interface protocols such as a USB (universal serial bus) protocol, an MMC (multimedia card) protocol, a PCI (peripheral component interconnection) protocol, a PCI-E (PCI-express) protocol, a PATA (parallel advanced technology attachment) protocol, a SATA (serial ATA) protocol, an SCSI (small computer small interface) protocol, an SAS (serial attached SCSI) protocol, and an IDE (integrated drive electronics) protocol.

The memory interface 1213 may be configured to interface the controller 1210 with the data storage medium 1220 and configured to provide a command and an address to the data storage medium 1220. Furthermore, the memory interface 1213 may be configured to exchange data with the data storage medium 1220.

The error correction code unit 1215 may be configured to detect an error of the data read from the data storage medium 1220. Also, the error correction code unit 1215 may be configured to correct the detected error when the detected error is within a correction range. The error correction code unit 1215 may be provided inside or outside the controller 1210 depending on the memory system 1000.

The data storage medium 1220 may include a plurality of semiconductor memory devices NVM0 to NVMk, each of which may be constituted by the semiconductor memory device (the reference numeral 100 of FIG. 1) in accordance with an embodiment of the present invention. According to a sleep mode command provided from the controller 1210, each of the semiconductor memory devices NVM0 to NVMk may enter a sleep mode. Even though each of the semiconductor memory devices NVM0 to NVMk enters the sleep mode, the external power may always be supplied to a CAM block. Therefore, setting information stored in the CAM block of each of the semiconductor memory devices NVM0 to NVMk can always be retained. If each of the semiconductor memory devices NVM0 to NVMk enters the sleep mode, a power block of each of the semiconductor memory devices NVM0 to NVMk may not generate internal power.

The controller 1210 and the data storage medium 1220 may be configured as a solid state drive (SSD).

As another example, the controller 1210 and the data storage medium 1220 may be integrated into one semiconductor apparatus and may be configured as a memory card. For example, the controller 1210 and the data storage medium 1220 may be integrated into one semiconductor apparatus and may be configured as a PCMCIA (personal computer memory card international association) card, a CF (compact flash) card, a smart media card, a memory stick, a multimedia card (MMC, RS-MMC and MMC-micro), an SD (secure digital) card (SD, Mini-SD and Micro-SD), a UFS (universal flash storage), etc.

In another example, the controller 1210 or the data storage medium 1220 may be mounted as various types of packages. For example, the controller 1210 or the data storage medium 1220 may be mounted by being packaged into types such as a POP (package on package), a ball grid array (BGA) package, a chip scale package (CSP), a plastic leaded chip carrier (PLCC), a plastic dual in-line package (PDIP), a die in waffle pack, a die in wafer form, a chip on board (COB), a ceramic dual in-line package (CERDIP), a plastic metric quad flat package (MQFP), a thin quad flat package (TQFP), a small outline IC (SOIC), a shrink small outline package (SSOP), a thin small outline package (TSOP), a thin quad flat package (TQFP), a system in package (SIP), a multi-chip package (MCP), a wafer-level fabricated package (WFP), and a wafer-level processed stack package (WSP).

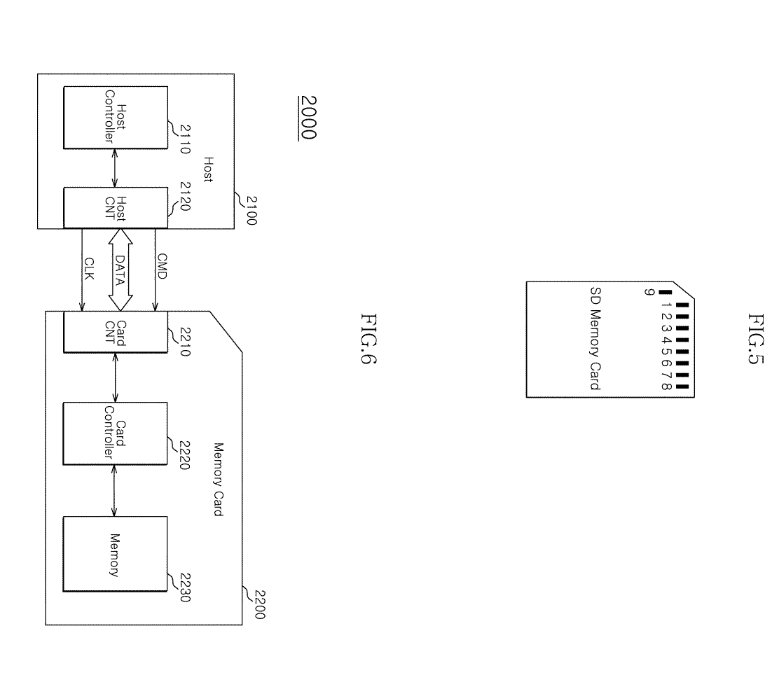

Referring to FIG. 5, an SD (secure digital) card may include one command pin (for example, a second pin), one clock pin (for example, a fifth pin), four data pins (for example, first, seventh, eighth and ninth pins), and three power pins (for example, third, fourth and sixth pins).

A command and a response signal may be transmitted by the command pin (the second pin). In general, the command may be transmitted to the SD card from a host, and the response signal may be transmitted to the host from the SD card.

The data pins (the first, seventh, eighth and ninth pins) may be divided into reception (Rx) pins for receiving data transmitted from the host and transmission (Tx) pins for transmitting data to the host. The reception (Rx) pins and the transmission (Tx) pins may be provided in pairs to transmit differential signals.

Referring to FIG. 6, a data processing system 2000 may include a host 2100 and a memory card 2200. The host 2100 may include a host controller 2110 and a host connection (Host CNT) unit 2120. The memory card 2200 may include a card connection (Card CNT) unit 2210, a card controller 2220, and a memory device 2230.

The host connection unit 2120 and the card connection unit 2210 may be configured to include a plurality of pins, respectively. The pins may include a command pin, a clock pin, a data pin, and a power pin. The number of pins may change depending on the kind of the memory card 2200.

The host 2100 may store data in the memory card 2200 or may read data stored in the memory card 2200.

The host controller 2110 may transmit a write command CMD, a clock signal CLK generated from a clock generator (not shown) in the host 2100, and data DATA to the memory card 2200 through the host connection unit 2120. The card controller 2220 may operate in response to the write command received through the card connection unit 2210. The card controller 2220 may store the received data DATA in the memory device 2230, using a clock signal generated from a clock generator (not shown) in the card controller 2220, according to the received clock signal CLK.

The host controller 2110 may transmit a read command CMD and a clock signal CLK generated from a clock generator (not shown) in the host 2100 to the memory card 2200 through the host connection unit 2120. The card controller 2220 may operate in response to the read command received through the card connection unit 2210. The card controller 2220 may read data from the memory device 2230 using a clock signal generated from a clock generator (not shown) in the card controller 2220, according to the received clock signal CLK, and may transmit the read data to the host controller 2110.

The semiconductor memory device 2230 may enter a sleep mode according to a sleep mode command provided from the card controller 2220. Even though the semiconductor memory device 2230 enters the sleep mode, external power may always be supplied to a CAM block. Therefore, setting information stored in the CAM block of the semiconductor memory device 2230 may always be retained. If the semiconductor memory device 2230 enters the sleep mode, a power block of the semiconductor memory device 2230 may not generate internal power.

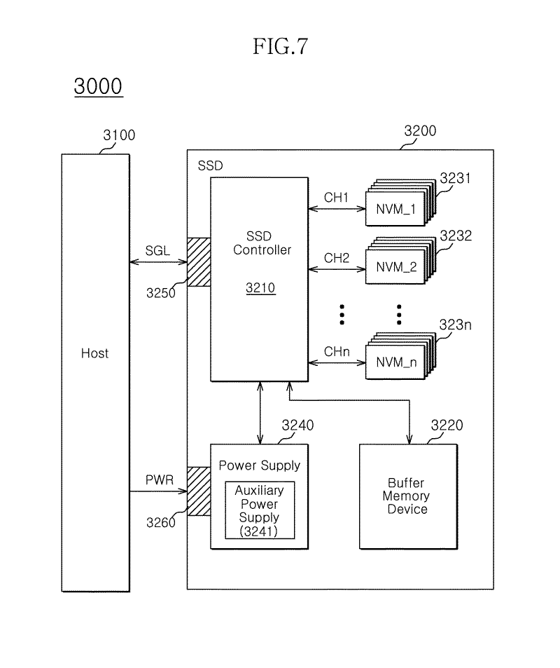

Referring to FIG. 7, a data processing system 3000 may include a host 3100 and an SSD 3200.

The SSD 3200 may include an SSD controller 3210, a buffer memory device 3220, semiconductor memory devices 3231 to 323n, a power supply 3240, a signal connector 3250, and a power connector 3260.

The SSD 3200 is operated in response to an operating request from the host 3100. That is to say, the SSD controller 3210 may be configured to access the semiconductor memory devices 3231 to 323n in response to the operating request from the host 3100. For example, the SSD controller 3210 may be configured to control read, program and erase operations of the semiconductor memory devices 3231 to 323n.

The buffer memory device 3220 may be configured to temporarily store data which are to be stored in the semiconductor memory devices 3231 to 323n. Further, the buffer memory device 3220 may be configured to temporarily store data which are read from the semiconductor memory devices 3231 to 323n. The data temporarily stored in the buffer memory device 3220 may be transmitted to the host 3100 or the semiconductor memory devices 3231 to 323n under the control of the SSD controller 3210.

The semiconductor memory devices 3231 to 323n may be used as storage media for the SSD 3200. The semiconductor memory devices 3231 to 323n may be connected to the SSD controller 3210 through a plurality of channels CH1 to CHn, respectively. One or more semiconductor memory devices may be connected to one channel. The semiconductor memory devices connected to one channel may be connected to the same signal bus and data bus.

According to a sleep mode command provided from the SSD controller 3210, each of the semiconductor memory devices 3231 to 323n may enter a sleep mode. Even though each of the semiconductor memory devices 3231 to 323n enters the sleep mode, external power is always supplied to a CAM block. Therefore, setting information stored in the CAM block of each of the semiconductor memory devices 3231 to 323n may always be retained. If each of the semiconductor memory devices 3231 to 323n enters the sleep mode, a power block of each of the semiconductor memory devices 3231 to 323n may not generate internal power.

The power supply 3240 may be configured to provide power PWR inputted through the power connector 3260 to the inside of the SSD 3200. The power supply 3240 may include an auxiliary power supply 3241. The auxiliary power supply 3241 may be configured to supply power so as to allow the SSD 3200 to be normally terminated when sudden power-off occurs. The auxiliary power supply 3241 may include super capacitors capable of being charged with power PWR.

The SSD controller 3210 may communicate a signal SGL with the host 3100 through the signal connector 3250. The signal SGL may include a command, an address, data, and the like. The signal connector 3250 may be constituted by a connector such as PATA (parallel advanced technology attachment), SATA (aerial advanced technology attachment), SCSI (small computer small interface), SAS (serial SCSI), and the like, according to an interface scheme between the host 3100 and the SSD 3200.

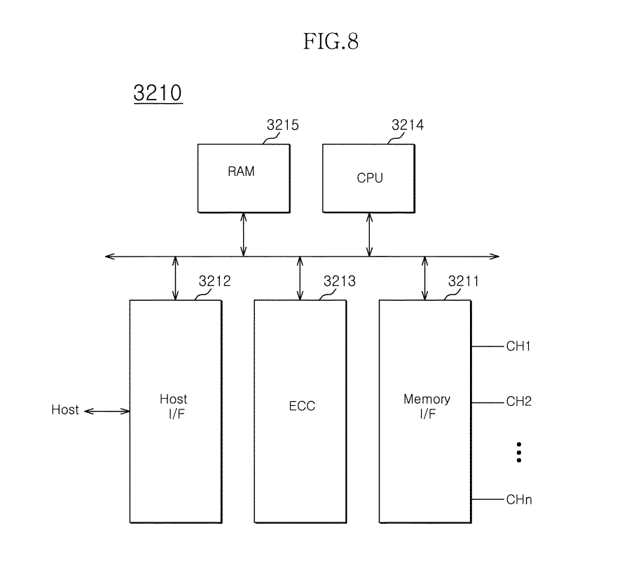

Referring to FIG. 8, the SSD controller 3210 may include a memory interface 3211, a host interface 3212, an ECC unit 3213, a central processing unit 3214, and a RAM 3215.

The memory interface 3211 may be configured to provide the command and the address to the semiconductor memory devices 3231 to 323n. Moreover, the memory interface 3211 may be configured to communicate data with the semiconductor memory devices 3231 to 323n. The memory interface 3211 may scatter data transmitted from the buffer memory device 3220 to the respective channels CH1 to CHn, under the control of the central processing unit 3214. Furthermore, the memory interface 3211 may transmit data read from the semiconductor memory devices 3231 to 323n to the buffer memory device 3220, under the control of the central processing unit 3214.

The host interface 3212 may be configured to provide an interface with the SSD 3200 in correspondence to the protocol of the host 3100. For example, the host interface 3212 may be configured to communicate with the host 3100 through one of PATA (parallel advanced technology attachment), SATA (serial advanced technology attachment), SCSI (small computer small interface) and SAS (serial SCSI) protocols. In addition, the host interface 3212 may perform a disk emulation function of supporting the host 3100 to recognize the SSD 3200 as a hard disk drive (HDD).

The ECC unit 3213 may be configured to generate parity bits based on the data transmitted to the semiconductor memory devices 3231 to 323n. The generated parity bits may be stored in spare areas of the semiconductor memory devices 3231 to 323n. The ECC unit 3213 may be configured to detect an error of data read from the semiconductor memory devices 3231 to 323n. When the detected error is within a correction range, the ECC unit 3213 may be configured to correct the detected error.

The central processing unit 3214 may be configured to analyze and process a signal SGL inputted from the host 3100. The central processing unit 3214 may control general operations of the SSD controller 3210 in response to a request from the host 3100. The central processing unit 3214 may control the operations of the buffer memory device 3220 and the semiconductor memory devices 3231 to 323n according to a firmware for driving the SSD 3200. The RAM 3215 may be used as a working memory device for driving the firmware.

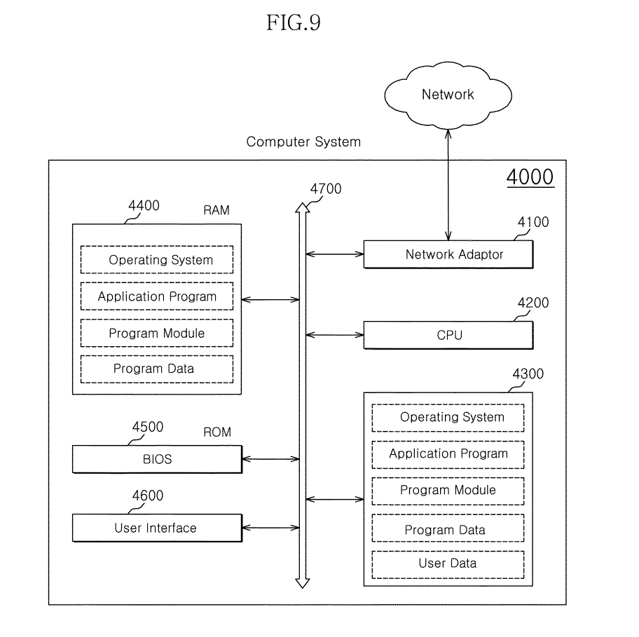

Referring to FIG. 9, a computer system 4000 may include a network adaptor 4100, a central processing unit 4200, a data storage device 4300, a RAM 4400, a ROM 4500 and a user interface, which are electrically connected to a system bus 4700. The data storage device 4300 may be constituted by the data storage device 1200 shown in FIG. 4 or the SSD 3200 shown in FIG. 7.

The network adaptor 4100 may provide interfacing between the computer system 4000 and external networks. The central processing unit 4200 may perform general operation processing for driving an operating system residing at the RAM 4400 or an application program.

The data storage device 4300 may store general data necessary in the computer system 4000. For example, an operating system for driving the computer system 4000, an application program, various program modules, program data and user data are stored in the data storage device 4300.

The RAM 4400 may be used as a working memory device of the computer system 4000. Upon booting, the operating system, the application program, the various program modules and the program data necessary for driving programs, which are read from the data storage device 4300, may be loaded on the RAM 4400. A BIOS (basic input/output system) which is activated before the operating system is driven may be stored in the ROM 4500. Information exchange between the computer system 4000 and a user may be implemented through the user interface 4600.

Although not shown in a drawing, it is to be readily understood that the computer system 4000 may further include devices such as an application chipset, a camera image processor (CIS), and the like.

As is apparent from the above descriptions, according to various embodiments of the present invention, the operating speed of a semiconductor memory device can be improved, and the standby current consumption of the semiconductor memory device can be reduced.

While certain embodiments have been described above, it will be understood to those skilled in the art that the embodiments described are by way of example only. Accordingly, the semiconductor memory device and the data storage device including the same described herein should not be limited based on the described embodiments. Rather, the semiconductor memory device and the data storage device including the same described herein should only be limited in light of the claims that follow when taken in conjunction with the above description and accompanying drawings.

What is claimed is:

1. A semiconductor memory device comprising:
a power block configured to generate an internal voltage based on an external voltage;
a circuit block configured to operate according to the internal voltage and drive memory cells; and
a CAM (content addressed memory) block configured to operate according to the external voltage and store setting information necessary for driving of the memory cells.

2. The semiconductor memory device according to claim 1, wherein the CAM block is activated regardless of an operation mode of the semiconductor memory device.

3. The semiconductor memory device according to claim 2, wherein the CAM block is activated while the semiconductor memory device operates in an inactive mode.

4. The semiconductor memory device according to claim 3, wherein the inactive mode includes a power saving mode.

5. The semiconductor memory device according to claim 1, further comprising:
a power pad configured to electrically connect to the power block and to receive the external voltage.

6. The semiconductor memory device according to claim 5, wherein the CAM block is configured to be directly provided with the external voltage through the power pad.

7. The semiconductor memory device according to claim 1, wherein the power block is configured to interrupt generation of the internal voltage while the semiconductor memory device operates in the inactive mode.

8. The semiconductor memory device according to claim 7, wherein the power block comprises:
a power generating block configured to generate the internal voltage based on the external voltage;
an external power blocking block configured to block the external voltage from being transferred to the power generating block while the semiconductor memory device operates in the inactive mode; and
a discharging block configured to discharge the power generating block while the semiconductor memory device operates in the inactive mode.

9. The semiconductor memory device according to claim 8, wherein the discharging block is configured to provide a ground voltage to input terminals of the power generating block while the semiconductor memory device operates in the inactive mode.

10. A data storage device comprising:
a semiconductor memory device; and
a controller configured to control the semiconductor memory device,
wherein the semiconductor memory device comprises:
a power block configured to generate an internal voltage based on an external voltage which is applied through a power pad;
a circuit block configured to operate according to the internal voltage and drive memory cells; and
a CAM (content addressed memory) block configured to operate according to the external voltage and store setting information necessary for driving of the memory cells.

11. The data storage device according to claim 10, wherein the semiconductor memory device is configured to operate in a power saving mode according to a power save command provided from the controller.

12. The data storage device according to claim 11, wherein the CAM block is activated while the semiconductor memory device operates in the power saving mode.

13. The data storage device according to claim 12, wherein the CAM block is configured to be directly provided with the external voltage through the power pad.

14. The data storage device according to claim 11, wherein the power block is configured to interrupt generation of the internal voltage while the semiconductor memory device operates in the power saving mode.

15. The data storage device according to claim 14, wherein the power block comprises:
a power generating block configured to generate the internal voltage based on the external voltage;
an external power blocking block configured to block the external voltage from being transferred to the power generating block while the semiconductor memory device operates in the power saving mode; and
a discharging block configured to discharge the power generating block while the semiconductor memory device operates in the power saving mode.

16. The data storage device according to claim 11, wherein the semiconductor memory device is configured to operate in an active mode instead of the power saving mode when an activated chip select signal is provided from the controller.

17. The data storage device according to claim 10, wherein the semiconductor memory device and the controller are constituted by a solid state drive (SSD).

18. A semiconductor system comprising:
a memory device configured to operate in response to a plurality of driving modes; and
a CAM (content addressed memory) block configured to is continuously operate regardless of the plurality of driving modes.

19. The system according to claim 18, wherein the plurality of driving mode includes:
an active mode for providing a power to the memory device; and
a deactive mode for blocking the power from the memory device.

20. The system according to claim 18, further comprising:
a controller for determining the plurality of driving modes.
